(19) United States
(12) Patent Application Publication
(10) Pub. No.: US 2025/0233118 A1
(43) Pub. Date: Jul. 17, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Yu KE, Taichung City (TW); Liang-Pin CHEN, Taichung City (TW)

(21) Appl. No.: 18/757,105

(22) Filed: Jun. 27, 2024

(30) Foreign Application Priority Data
Jan. 12, 2024 (TW) 113101411

(51) Int. Cl. H01L 25/16; G02B 6/42; H01L 23/00; H01L 25/00

(52) U.S. Cl. CPC H01L 25/167; G02B 6/4243; H01L 25/50; H01L 24/16; H01L 24/32; H01L 24/73; H01L 2224/16148; H01L 2224/16227; H01L 2224/32225; H01L 2224/73204; H01L 2924/1436

(57) ABSTRACT

An electronic package is provided, which comprises: a carrier structure; an electronic element disposed on and electrically connected to the carrier structure; a supporting structure disposed on the carrier structure; a semiconductor element disposed on the carrier structure; and an optoelectronic element disposed on, electrically connected to the semiconductor element and partially supported by the supporting structure. By the implementation of the present disclosure, the optoelectronic element in the electronic package and/or the optical fiber connected to the electronic package can obtain a well and firm support, avoiding the breakage of the optoelectronic element and/or the optical fiber, so as to improve the manufacturing yield, the reliability and the service life of the electronic package.

### CROSS-REFERENCE TO RELATED APPLICATIONS

The present application is based upon and claims the right of priority to TW Patent Application No. 113101411, filed Jan. 12, 2024, the disclosure of which is hereby incorporated by reference herein in its entirety for all purposes.

### BACKGROUND

### 1. Technical Field

The present disclosure relates to a semiconductor device, and more particularly, to an electronic package with photonic elements and manufacturing method thereof.

### 2. Description of Related Art

With the vigorous development of electronic industries, electronic products gradually move toward multifunction and high performance. The current application of fifth-generation (5G) communication technology has expanded to various fields such as internet of things (IoT), industrial internet of things (IIoT), cloud, artificial intelligence (AI), autonomous car and medical, and with the expansion of the application level, the generation of a large amount of data needs to be efficiently transmitted, calculated and stored, especially the requirements for data transmission is emerged in huge amount, causing industries to begin with “light” instead of “electric” as carrier of data transmission, thereby improving transmission capacity, efficiency or distance, and reducing energy consumption during the transmission process. Under this background, silicon photonic elements and application products thereof as well as co-package optic have become the development trend of future semiconductor and packaging technology.

FIG. 1A and FIG. 1B are schematic cross-sectional views of a conventional co-package optical semiconductor package 1. As shown in FIG. 1A, a substrate 10 of a semiconductor package 1 is disposed with an electronic integrated circuit (electronic IC, ETC) element 11A, an electronic element 11B and a photonic integrated circuit (photonic IC, PIC) element 12 bonded above an electronic integrated circuit element 11A. One side end of the photonic integrated circuit element 12 is connected to an optical fiber 70, and a shelf 13 is disposed below the connection between the photonic integrated circuit element 12 and the optical fiber 70.

However, in the aforementioned conventional semiconductor package 1, in order to connect the photonic integrated circuit element 12 to the optical fiber 70, an end connected to the optical fiber 70 must be adjacent to or even protrude from a side of the substrate 10. Although there is a shelf 13 disposed below the connection therebetween, the shelf 13 is not firmly supported since the shelf 13 is located outside the semiconductor package 1. In this case, when the connected optical fiber is subjected to an external force caused by being shaken or pulled, the photonic integrated circuit element 12 adjacent to its connection with the optical fiber 70 prone to occur breakage as shown in FIG. 1B, resulting in loss of reliability and service life. The structure which slightly protrudes from the substrate 10 may be damaged due to collision during the manufacturing process, thus reducing the yield of the manufacturing process.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; an electronic element disposed on the carrier structure and electrically connected to the carrier structure; a supporting structure disposed on the carrier structure; a semiconductor element disposed on the carrier structure and electrically connected to the carrier structure; and an optoelectronic element disposed on the semiconductor element and electrically connected to the semiconductor element, wherein the optoelectronic element is partially supported by the supporting structure.

The present disclosure also provides a manufacturing method of an electronic package, which comprises: providing a carrier structure; disposing an electronic element on the carrier structure, and electrically connecting the electronic element to the carrier structure; disposing a supporting structure on the carrier structure; disposing a semiconductor element on the carrier structure, and electrically connecting the semiconductor element to the carrier structure; and disposing an optoelectronic element on the semiconductor element in a manner that the optoelectronic element is partially supported by the supporting structure and electrically connecting the optoelectronic element to the semiconductor element.

In the aforementioned electronic package and manufacturing method thereof, the semiconductor element is an electronic integrated circuit (EIC).

In the aforementioned electronic package and manufacturing method thereof, the optoelectronic element is a photonic integrated circuit (PIC).

In the aforementioned electronic package and manufacturing method thereof, the optoelectronic element is connected to an optical fiber.

In the aforementioned electronic package and manufacturing method thereof, the optical fiber passes through at least a part of the top of the supporting structure.

In the aforementioned electronic package and manufacturing method thereof, the supporting structure is formed with grooves, so that at least a part of the optical fiber is accommodated in the grooves.

In the aforementioned electronic package and manufacturing method thereof, the supporting structure is formed with a protecting layer, allowing at least a part of the optical fiber to be fixed by the protecting layer.

In the aforementioned electronic package and manufacturing method thereof, the supporting structure is made of thermal conductive material.

In the aforementioned electronic package and manufacturing method thereof, the electronic element is a switch chip.

As can be understood from the above, in the electronic package and manufacturing method thereof of the present disclosure, the supporting structure is disposed on the carrier structure, so that the optoelectronic element in the electronic package and/or the optical fiber connected to the electronic package are well and firmly supported to avoid the optoelectronic element and/or the optical fiber broken near the connection, thereby improving the manufacturing yield and the reliability and service life of the electronic package during use.

### BRIEF DESCRIPTION OF THE DRAWINGS

FIG. 1A to FIG. 1B are schematic cross-sectional views of a conventional co-package optical semiconductor package.

FIG. 2A to FIG. 2C are schematic cross-sectional views of a manufacturing method of an electronic package of the present disclosure.

FIG. 2B-2 is a schematic top view of a manufacturing method of an electronic package of the present disclosure.

FIG. 2D is a schematic top view of an embodiment of an electronic package of the present disclosure.

FIG. 3A to FIG. 3C are schematic side views of a supporting structure of an electronic package of the present disclosure in different embodiments.

### DETAILED DESCRIPTION

The following describes the implementation of the present disclosure with examples. Those skilled in the art can easily understand the other advantages and effects of the present disclosure from the content disclosed in this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “third,” “a,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

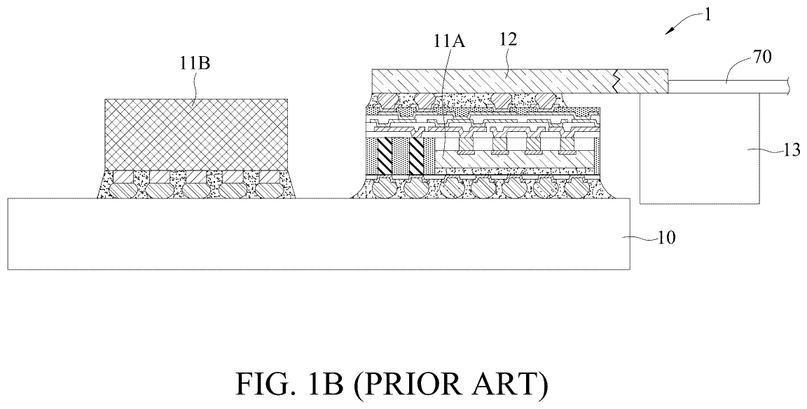

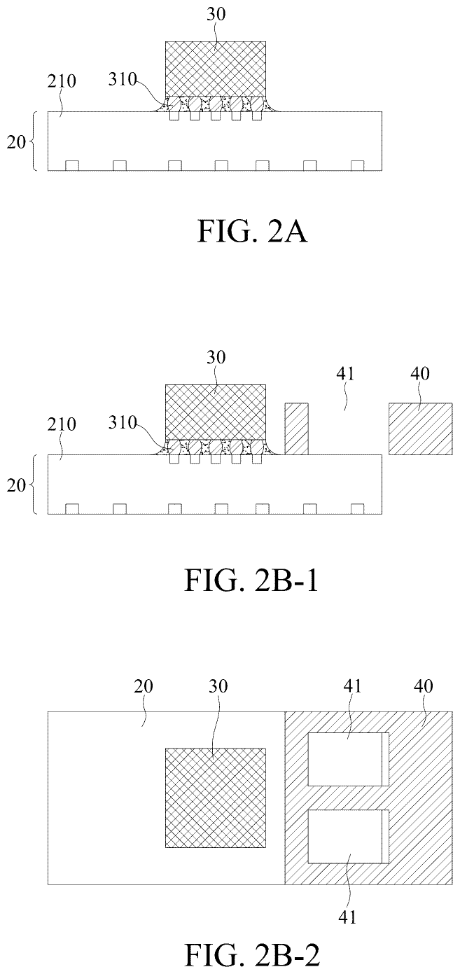

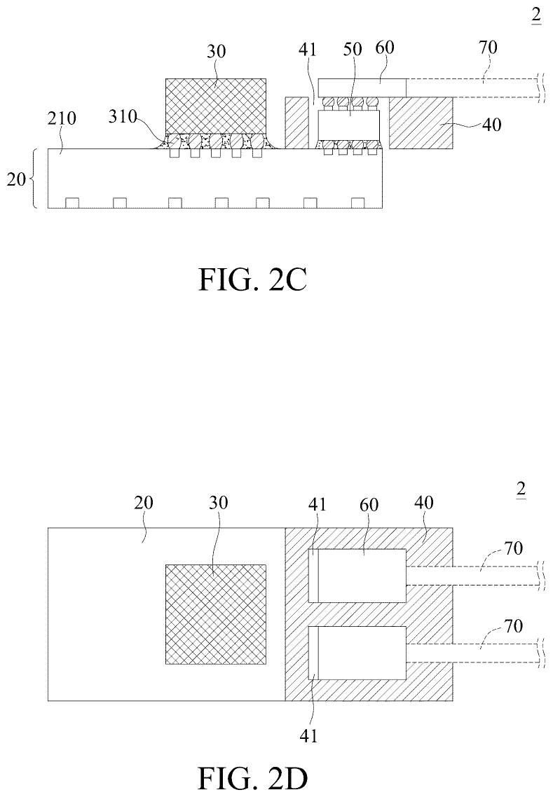

FIG. 2A to FIG. 2C are schematic cross-sectional views of a manufacturing method of an electronic package 2 of the present disclosure.

As shown in FIG. 2A, a carrier structure 20 is provided at first. The carrier structure 20 can be a redistribution layer (RDL) structure or a semiconductor package substrate. The carrier structure 20 of the embodiment is a semiconductor package substrate, such as a package substrate with a core layer or a coreless circuit structure, and the circuit structure includes at least one insulating layer 210 and at least one circuit layer (not shown) connected to the insulating layer 210. The material of the insulating layer 210 is, for example, dielectric materials such as polybenzoxazole (PBO), polyimide (PI), prepreg (PP). The circuit layer is, for example, a fan out redistribution layer. It should be understood that the carrier structure 20 can also be other boards, such as lead frames, wafers, or other carrier boards with metal routing, but the present disclosure is not limited to as such.

Next, an electronic element 30 is disposed on the carrier structure 20 and electrically connected to the carrier structure 20.

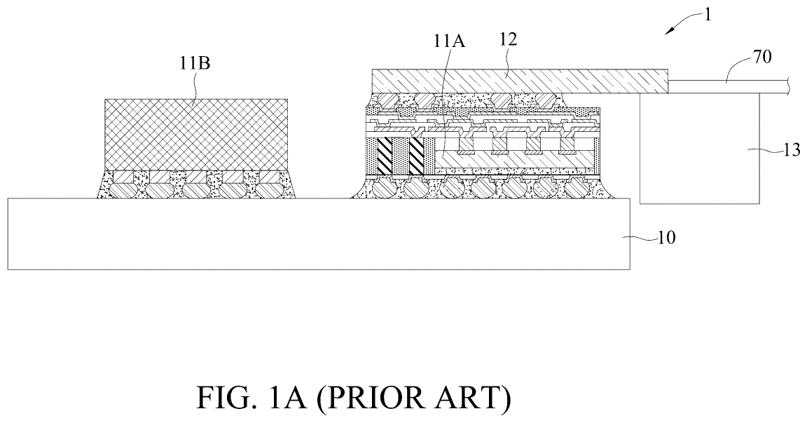

Then, as shown in FIG. 2B-1 and FIG. 2B-2, a supporting structure 40 is disposed on one side of the carrier structure 20. The supporting structure 40 is formed with slots 41 in connection to its top surface and its bottom surface, such that a bottom of the slot 41 can be exposed from a part of the surface of the carrier structure 20.

As shown in FIG. 2C, a semiconductor element 50 is disposed in each of the slots 41 of the supporting structure 40 respectively. Each semiconductor 50 is electrically connected to the carrier structure 20 exposed from the bottom of the slot 41, and a height of the semiconductor element 50 does not exceed a height of the supporting structure 40 around it, thus the top surface will not be higher than the periphery of the slot 41.

Then, an optoelectronic element 60 is disposed on a semiconductor element 50. A portion of the bottom of the optoelectronic element 60 is connected to the semiconductor element 50 and is electrically connected to the semiconductor element 50. The other end of the optoelectronic element 60 is located outside the slot 41 and abutted against the supporting structure 40 to be supported by the supporting structure 40. That is, the optoelectronic element 60 is partially supported by the supporting structure 40, so that even if one end of the optoelectronic element 60 near the outer periphery is subjected to an external force, especially an external force in the up and down direction, the optoelectronic element 60 is prevented from breaking or being damaged, thereby improving the yield of the process.

Specifically, one or more electronic elements 30 can be disposed on the carrier structure 20. To simplify the description, in this embodiment, only one electronic element 30 is disposed as an example. The electronic element 30 can be a switch chip, a high bandwidth memory (HBM) chip or other active elements such functional chip, or a passive element such as a resistor, a capacitor, or an inductor. As long as the elements can meet the designed functional requirements, but the present disclosure is not limited as such.

Electronic element 30 can be electrically connected to the carrier structure 20 in a flip-chip manner by a plurality of conductive bumps 310 such as solder bumps, copper bumps, or others, for instance, being electrically connected to the circuit layer 20 disposed on the surface of the carrier structure 20 or inside the carrier structure 20 (not shown). In practice, there are various ways for the electronic element 30 to be electrically connected to the carrier structure 20, and the present disclosure is not limited to as such.

The number of the semiconductor element 50 and the optoelectronic element 60 can be one or more, depending on functional requirements of the electronic package 2. In this embodiment, two semiconductor elements 50 are disposed on the carrier structure 20 for example. The semiconductor elements 50 can be a variety of active elements or passive elements, such as electronic integrated circuit (electronic IC, EIC), but the present disclosure is not limited to as such.

In order to allow the semiconductor element 50 to be disposed on the carrier structure 20 and electrically connected to the carrier structure 20, the supporting structure 40 is provided with slots 41 at positions corresponding to the semiconductor elements 50 to accommodate each semiconductor element 50 in the slot 41. In this embodiment, a slot 41 is formed on the supporting structure 40 at a position corresponding to the semiconductor element 50, that is, a total of two slots 41 are formed on the supporting structure 40 as an example. In other aspects, only one larger slot 41 is formed on the supporting structure 40 and accommodates multiple semiconductor elements 50 therein. In this regard, the present disclosure is not limited to as such.

The optoelectronic element 60 is disposed on the semiconductor element 50 and protrudes from the slot 41, and the optoelectronic element 60 is electrically connected to the semiconductor element 50 below. The part of the optoelectronic element 60 close to outer periphery of the carrier structure 20 is abutted against the top of the supporting structure 40 and is supported by the supporting structure 40.

As for types of the optoelectronic element 60, it can be a photoelectric converter, an optical signal receiver, an optical signal transmitter, or a photon integrated circuit (photonic IC, PIC) that meets functional requirements. In an embodiment, there are two optoelectronic elements 60, for example, one of the two optoelectronic elements 60 can be used to receive optical signals, while the other one can be used to transmit optical signals, or they can be the same type of the optoelectronic element 60 connected to two different external signal sources respectively. This all depends on functional designs of the package, and there is no specific limitation.

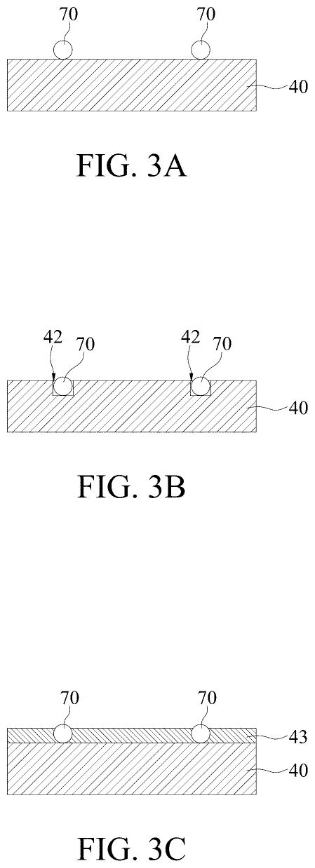

In practical applications, the optoelectronic element 60 is connected to the external optical fiber 70 to receive or transmit optical signals. In order to have better support and protection on the connection between the optoelectronic element 60 and the optical fiber 70 to prevent breakage, the optical fiber 70 connected to the optoelectronic element 60 will pass through at least a part of the top of the supporting structure 40. Besides, as shown in FIG. 3A, the top part of the supporting structure 40 passed through by the optical fiber 70 is supported by the supporting structure 40. In this regard, in addition to allowing the optoelectronic element 60 to be supported and protected by the supporting structure 40, it can also avoid damage to the optoelectronic element 60 due to accidental movement of the optical fiber in the vertical direction.

In addition, as shown in FIG. 3B, in order to provide a better support effect, grooves 42 can be further formed on the supporting structure 40, such that at least a part of the optical fiber 70 is accommodated and fixed in the corresponding grooves 42. In this regard, the optical fiber 70 can be not only supported in the vertical direction, but also fixed or limited in the horizontal direction, so that it will not accidentally move in these two directions and affect the optoelectronic element 60, which would otherwise result in damage or even breakage to the optoelectronic element 60.

In addition to the above-mentioned method of fixing or limiting the optical fiber 70 through grooves 42, a protecting layer 43 can also be disposed on the supporting structure 40 as shown in FIG. 3C, and at least a part of each optical fiber 70 can be fixed in the protecting layer 43. This can also achieve the purpose of limiting the accidental movement of the optical fiber 70 in the horizontal direction.

The protecting layer 43 can be polyimide (PI), dry film, or molding colloid or molding compound of epoxy, or it can be material such as green paint or ink which is formed on the supporting structure 40 by methods such as liquid compounding or injection, and at least the bottom of the optical fiber 70 is disposed therein before the material is cured. Then, after the protecting layer 43 is cured, the optical fiber 70 can be firmly fixed with the protecting layer 43. Of course, the material of the protecting layer 43 can also use any other suitable material, but the present disclosure is not limited to as such.

In certain preferred embodiments, the supporting structure 40 can also be made of thermal conductive materials. It is even possible to allow an inner wall of the slot 41 of the supporting structure 40 made of thermal conductive material to form thermal contact with the semiconductor element 50 in the slot 41 and the optoelectronic element 60 abutting against the supporting structure 40. In this regard, in addition to providing support for the optoelectronic element 60, the supporting structure 40 can also help the optoelectronic element 60 or even the semiconductor element 50 and the carrier structure 20 positioned thereunder rapidly conduct and dissipate the heat generated during the operation, and can further improve the reliability and service life of the electronic package 2.

In addition to the aforementioned manufacturing method, the present disclosure also provides an electronic package 2 corresponding to the manufacturing method. The electronic package 2 comprises: a carrier structure 20; an electronic element 30 disposed on the carrier structure 20 and electrically connected to the carrier structure 20; a supporting structure 40 disposed on the carrier structure 20; a semiconductor element 50 disposed on the carrier structure 20 and electrically connected to the carrier structure 20, and a height of the semiconductor element 50 is less than a height of the supporting structure 40; and an optoelectronic element 60 disposed on the semiconductor element 50, electrically connected to the semiconductor element 50, and partially supported by the supporting structure 40.

In an embodiment, the semiconductor element 50 is an electronic integrated circuit (EIC).

In an embodiment, the optoelectronic element 60 is a photonic integrated circuit (PIC).

In an embodiment, the optoelectronic element 60 is connected to an optical fiber 70.

In an embodiment, the optical fiber 70 is passed through at least part of the top of the supporting structure 40.

In an embodiment, the supporting structure 40 is formed with grooves 42, so that at least part of the optical fiber 70 is accommodated in the grooves 42.

In an embodiment, the supporting structure 40 is provided with a protecting layer 43, for at least a part of the optical fiber 70 to be fixed by the protecting layer 43.

In an embodiment, the supporting structure 40 is made of thermal conductive material.

In an embodiment, the electronic element 30 is a switch chip.

In view of the above, in the electronic package 2 and manufacturing method thereof of the present disclosure, a supporting structure 40 is disposed on a carrier structure 20, so that the optoelectronic element 60 in the electronic package 2 and/or the optical fiber 70 connected to the electronic package 2 are well and firmly supported to avoid the optoelectronic element 60 and/or the optical fiber 70 broken near the connection, thereby improving the manufacturing yield and the reliability and service life of the electronic package 2 during use.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic element disposed on the carrier structure and electrically connected to the carrier structure;
a supporting structure disposed on the carrier structure;
a semiconductor element disposed on the carrier structure and electrically connected to the carrier structure; and
an optoelectronic element disposed on the semiconductor element, electrically connected to the semiconductor element, and partially supported by the supporting structure.

2. The electronic package of claim 1, wherein the semiconductor element is an electronic integrated circuit.

3. The electronic package of claim 1, wherein the optoelectronic element is a photonic integrated circuit.

4. The electronic package of claim 1, wherein the optoelectronic element is connected to an optical fiber.

5. The electronic package of claim 4, wherein the optical fiber is passed through at least part of a top of the supporting structure.

6. The electronic package of claim 5, wherein the supporting structure is formed with grooves, for at least a part of the optical fiber to be accommodated in the grooves.

7. The electronic package of claim 5, wherein the supporting structure is provided with a protecting layer, for at least a part of the optical fiber to be fixed by the protecting layer.

8. The electronic package of claim 1, wherein the supporting structure is made of thermal conductive material.

9. The electronic package of claim 1, wherein the electronic element is a switch chip.

10. A method of manufacturing an electronic package, comprising:
disposing an electronic element on a carrier structure, and electrically connecting the electronic element to the carrier structure;
disposing a supporting structure on the carrier structure;
disposing a semiconductor element on the carrier structure, and electrically connecting the semiconductor element to the carrier structure; and
disposing an optoelectronic element on the semiconductor element in a manner that the optoelectronic element is partially supported by the supporting structure and electrically connecting the optoelectronic element to the semiconductor element.

11. The method of claim 10, wherein the semiconductor element is an electronic integrated circuit.

12. The method of claim 10, wherein the optoelectronic element is a photonic integrated circuit.

13. The method of claim 10, wherein the optoelectronic element is connected to an optical fiber.

14. The method of claim 13, wherein the optical fiber is passed through at least a part of a top of the supporting structure.

15. The method of claim 14, wherein the supporting structure is formed with grooves, so that at least a part of the optical fiber is accommodated in the grooves.

16. The method of claim 14, wherein the supporting structure is disposed with a protecting layer, for at least a part of the optical fiber to be fixed by the protecting layer.

17. The method of claim 10, wherein the supporting structure is made of thermal conductive material.

18. The method of claim 10, wherein the electronic element is a switch chip.
